(19) United States
(12) Patent Application Publication
(10) Pub. No.: US 2011/0013366 A1
(43) Pub. Date: Jan. 20, 2011

(54) ELECTRONIC CIRCUIT BOARD WITH A THERMAL CAPACITOR

(75) Inventors: Luisa COPPOLA, Baden (CH); Didier Cottet, Zurich (CH); Matteo Fabbri, Adliswil (CH); Roland Schmidt, Wettingen (CH)

Correspondence Address: BUCHANAN, INGERSOLL & ROONEY PC, POST OFFICE BOX 1404, ALEXANDRIA, VA, 22313-1404, US

(73) Assignee: ABB RESEARCH LTD, Zurich (CH)

(21) Appl. No.: 12/835,961

(22) Filed: Jul. 14, 2010

(30) Foreign Application Priority Data
Jul. 16, 2009 (EP) 09165670.2

(51) Int. Cl. H05K 7/20

(52) U.S. Cl. 361/720

(57) ABSTRACT

An electronic circuit board includes at least one conductor path and at least one component which is one of an electronic component, electric component and heat emitting component, and which is connected to the conductor path. At least one thermal capacitor is thermally connected to the conductor in vicinity to the at least one component. The at least one thermal capacitor is suitable for transmitting and/or buffering thermal energy of the at least one component.

### RELATED APPLICATIONS

This application claims priority under 35 U.S.C. §119 to European Patent Application No. 09165670.2 filed in Europe on Jul. 16, 2009, the entire content of which is hereby incorporated by reference in its entirety.

### FIELD

The present disclosure relates to a thermal transport on a circuit board, such as an electronic circuit board, for example a printed circuit board (PCB), a direct bond copper (DBC), direct aluminum bond (DAB), or any rigid or flexible circuit board.

### BACKGROUND INFORMATION

The heat originating from thermal power dissipation caused by any part of the circuit board such as, for example, electronic, electric or other heat emitting components as well as the conductor paths, is usually transported away via conductor paths of the electronic circuit board or via the outer surface of the electronic components. It is also conceivable that a thermal load that is present in the at least one conductor path originates from an electric and/or electronic device or component that is not placed directly on the circuit board addressed in this description and/or due to a comparative high resistive loss of the conductor path on the board itself. The cooling performance via the outer surface can be intensified by the use of additional heat sinks mounted on the device to be cooled and/or fans. However, the present disclosure concentrates on the heat transportation via the conductor paths of the electronic circuit board. The temperature of electronic components should remain under a maximum temperature to prevent operating faults, life-time degradation or even serious damage of the electronic and/or electric components. The electric components on electronic circuit boards are heated up with the applied current in accordance with Joules first law. Therefore, the cooling performance of the electronic circuit board should respect the maximal appearing current to guarantee the removal of the thermal energy from the electronic component and to prevent heating up over a maximum allowed temperature of the electronic component even in peaks of the current. Such peaks in the current could appear in transients of electrical overload. This means that the cooling performance needs to be adapted thereto.

A plurality of techniques have been proposed to improve heat removal of the electronic circuit board or the amount of transported thermal energy via the conductor paths of the PCB. For example, UK Patent Application UK 2325082 A proposes a technique of heat dissipation in electronic components and the improvement of heat dissipation by the arrangement of through holes. However, the cooling performance of the PCB is adapted to the maximum current appearing in every electronic or other component on the PCB even if this current appears only for a short time such as transients of electrical overload. Thus, complex and expansive electronic circuit board designs have to be chosen only for handling the maximal short time currents in maybe only one electronic component. Since the heat generation is proportional to the quadratic current, the cooling performance has to be increased disproportionally for handling the maximal currents.

### SUMMARY

An exemplary embodiment provides an electronic circuit board. The exemplary electronic circuit board includes at least one conductor path, and at least one component. The at least one component is one of an electronic component, an electric component and a heat emitting component, and the component is connected to the at least one conductor path. The exemplary electronic circuit board also includes at least one thermal capacitor configured to buffer thermal energy in an operating state of the electronic circuit board. The at least one thermal capacitor is thermally connected to at least one of the conductor in vicinity to the at least one component, and the at least one conductor path. The at least one thermal capacitor includes at least one material having heat transportation properties for rapidly absorbing thermal energy discharged by the component during overload of the component over the conductor path in an operating state of the electronic circuit board.

### BRIEF DESCRIPTION OF THE DRAWINGS

Additional refinements, advantages and features of the present disclosure are described in more detail below with reference to exemplary embodiments illustrated in the drawings, in which:

FIG. 1 shows a first exemplary embodiment of an electronic circuit according to the present disclosure with the thermal capacitor mounted on the same side of the circuit board as the electronic component;

FIG. 2 shows a second exemplary embodiment of the electronic circuit using a different mounting technique;

FIG. 3 shows a third exemplary embodiment of the electronic circuit with the thermal capacitor being mounted on the other side;

FIG. 4 shows a diagram comparing temperature over time of conventional electronic circuits and of exemplary embodiments of the electronic circuit according to the present disclosure;

FIG. 5 shows a diagram comparing temperature over time of conventional electronic circuits and of exemplary embodiments of the electronic circuit according to the present disclosure;

FIG. 6 shows a fourth exemplary embodiment of the electronic circuit using increased thickness of a conductor path as a thermal capacitor

FIG. 7 shows a conductor path of a fifth exemplary embodiment of the present disclosure with an increased width; and

FIG. 8 shows a conductor path of a sixth exemplary embodiment of the present disclosure with a plurality of heat capacitors.

### DETAILED DESCRIPTION

Exemplary embodiments of the present disclosure provide an easy and inexpensive design of an electronic circuit board which allows heat to be safely removed from electronic components even during the time of overload currents.

An exemplary embodiment of the present disclosure provides an electronic circuit board. The electronic circuit board includes at least one conductor path. At least one component is thermally connected to the conductor path by connecting at least one terminal of the component to the conductor path. The component can be, for example, an electric component, an electronic component and/or a heat emitting component such as a resistor or even traces, vias or connectors in the circuit board, for example. A thermal capacitor suitable for buffering and/or transmitting thermal energy is also thermally connected in vicinity to the conductor path.

As used herein, the term “vicinity” connotes a relationship in terms of a distance between the at least one thermal capacitor and the at least one component. The distance is set such that a substantial portion of the thermal load emitted by the at least one component is received by the at least one thermal capacitor appointed to the at least one component. In other words, the term “vicinity” is used herein to describe the proximity or neighborhood of the at least one component. It shall not be understood of the at least one thermal capacitor in a narrow sense requiring that the at least one thermal capacitor is arranged directly aside the at least one component, since further components may be thermally and/or electrically connected to the conductor path between the at least one thermal capacitor and the at least one component, as long as the functional relationship between the at least one thermal capacitor and the at least one component remains essentially unaffected.

The thermal capacitor of the electronic circuit board absorbs the thermal energy discharged by the component during overload of the component over the conductor path, temporally buffers the energy, and slowly releases the heat to the conductor path and to an ambient environment of the circuit board, when a transient overload is finished and/or during the transient overload, such as a transient overload of the at least one component. Thus, the conductor paths or the design of the electronic circuit board and of the component itself can be constructed based on the normal operating current of the component without burdening the conductor path with the increased heat transportation during the overload current. The heat produced by short time maximum currents in single electronic or other components can be buffered in thermal capacitors next to these components.

Where applicable and feasible, the cooling effect may be increased in that the electronic circuit board includes at least one conductor path and at least one component as described above connected to the conductor path. The conductor path has a thermal capacitor region with an increased thickness and/or width compared to the normal thickness and/or width of the conductor path. The increased thickness and/or width is arranged in vicinity to the component suitable for buffering and/or transmitting thermal energy. Thus, if a thermal level of a conductor path needs to be lowered, broadening the conductor path or the conductor paths by widening and/or thickening the cross-section at a place other than in the vicinity of further thermal dissipating components becomes an option.

The exemplary thermal capacitor region can absorb the thermal energy discharged by the component in the neighborhood over the conductor path, temporally buffer the energy, and slowly release the heat to the conductor path, when a transient overload is finished. Thus, the conductor paths or the design of the electronic circuit board have to be adapted only in the region of the component and not over the complete circuit board.

In accordance with an exemplary embodiment, the thermal capacitor is thermally connected to the conductor path neighboring the component and on the same side of the circuit board as the component. Consequently, thermal energy can be conducted only over a small distance in the conductor path to the thermal capacitor.

Alternatively or in addition thereto, the thermal capacitor can be thermally connected to the conductor path on the other side of the component and opposing the component. This arrangement is advantageous in combination with the feature that the thermal capacitor is connected over the same connection to the conductor as the component and that the connection has a better heat transport capability than the conductor path. Thus, the heat generated by the component can be conducted without entering the conductor path to the component on the other side and be buffered there. The conductor path is not blocked by the suddenly increased amount of heat transported over the conductor path. By using connections which comprise a terminal of the component and solder having a bigger cross-sectional area in direction of the heat flow than the cross-sectional area of the conductor path, heat can rapidly be conducted to the thermal capacitor and at the same time heat can partly be conducted away over the conductor path. Therefore, optimized cooling effect of the component is achieved.

In accordance with an exemplary embodiment of the present disclosure, the thermal capacitor can be single bodied. Therefore, the thermal capacitor is easy and inexpensive to construct. The material should have good thermal properties. In other words, the at least one thermal capacitor can include at least one material having a heat conductance value of at least the heat conductance value of the conductor path, i.e. a good thermal conductivity. Depending on the requirements and the intended use, the thermal capacitor can even be made of a composite such as a metal matrix component, nano carbons, nano carbon tubes and the like. In accordance with an exemplary embodiment, the at least one thermal capacitor includes an aluminium and/or copper-based material having good properties of thermal conductance and a large heat capacity. Where applicable, the material of the heat capacitor can have at least a heat conductivity of the conductor path.

However, the thermal capacitor may comprise multiple parts instead of a monobloc body without deriving from the spirit of the present disclosure.

In accordance with an exemplary embodiment, the thermal capacitor is soldered to the conductor path. However, the present disclosure is not restricted to solder-connections, and includes connections such as clipping, brazing, press-fitting, sintering, and snap-fitting/clicking the thermal capacitor to the conductor path, for example. Where applicable, a fixation of the thermal capacitor including a thermal paste is also an option.

In accordance with an exemplary embodiment, the thermal capacitor can have the same or approximately similar dimensions as the component. Therefore, the thermal capacitor does not project over the component and does not need additional constructional space. In addition, on the one hand, the amount of heat absorbable in the thermal capacitor depends on the size of thermal capacitor and its heat capacitance and, on the other hand, the amount of heat generated in the component depends as well on the size of the component. The shape of the thermal capacitor can be chosen only in one direction or in only two directions similar to the component. For example, the height or the height and the depth of the thermal capacitor can be chosen to be similar to the component.

Another exemplary embodiment for saving space and being well combinable with the previously described embodiments is that a shape of the thermal capacitor on the side facing the component at least partly complimentarily corresponds to the form of the component on its side facing the thermal capacitor, such that the thermal capacitor can be mounted as close as possible to the component without touching it. For example, a shell surface of the thermal capacitor can be at least partially complementary to a shell surface of the at least one component. For example, the thermal capacitor can be mounted directly neighbored to the heat generating component. An exemplary embodiment of the heat capacitor surrounds the component with the shell surface being complementary to the shell surface of the at least one component. If the distance between the component and the heat capacitor is chosen adequate, a chimney effect arises. The chimney effect supports the cooling effect of the component and the heat capacitor.

In accordance with an exemplary embodiment, the thermal capacitor can be dimensioned in one direction at least as large as the width of the conductor path. Thus, the heat flow is not affected negatively by a bottleneck or a narrow point in the heat capacitor. Therefore, it is advantageous to connect a whole bottom surface of the thermal capacitor to the conductor path to prevent any narrow points in the heat flow.

In accordance with an another exemplary embodiment, the thermal capacitor can be formed as a closed block suitable for having small contact surface with the ambience. Such a form can be a cylinder or a general cuboid, for example. This form shows a minimal contact surface with the ambience, e.g., air. The dissipation of heat to the ambient environment is thereby slowed down, which reduces the airflow needed inside a electronic apparatus.

In accordance with an exemplary embodiment, the at least one thermal capacitor can be located at a distance from the at least one component, wherein the distance is set such that a thermal load being fed in the conductor path by the at least one component in an operating state of the electronic circuit remains below a preselected thermal threshold. According to an exemplary embodiment, at least two-thirds of the thermal load emitted from the at least one component can be received by the at least one thermal capacitor appointed to said at least one component.

In addition or alternatively thereto, a plurality of thermal capacitors is connected to the conductor path.

In accordance with an exemplary embodiment, a further component can be arranged between the component and the heat capacitor. For example, the further component can be insensible to heat.

In accordance with an exemplary embodiment, the heat capacity and heat conductivity of the heat capacitor is designed such that the additional heat of transient currents being higher than the nominal current of the component and/or the conductor path can be buffered in the heat capacitor for at least 100 sec, such as for 30 sec, for example. For calculating the heat amount arising in this period, a maximal occurring current can be used.

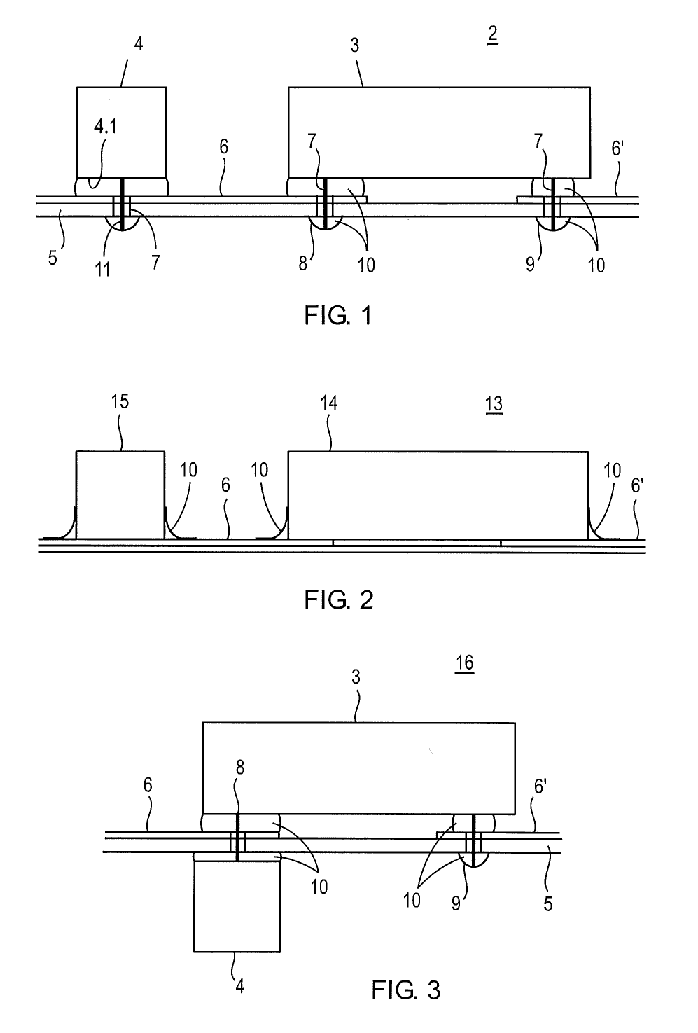

FIG. 1 shows a first exemplary embodiment of the present disclosure. The electronic circuit board 2 includes a power semiconductor component 3 as an example of an electronic component and a copper block 4 as a thermal capacitor. Instead of the power semiconductor component 3 illustrated in FIG. 1, heat emitting components such as resistors can be included on the electronic circuit board 2. The electronic circuit board 2 includes an insulating layer 5 and conductor paths 6 and 6′ attached to at least one side of the insulating layer 5. The electronic circuit board 2 includes through holes 7 in the region of the conductor paths 6 and 6′ for fixing the electronic component 3 on the electronic circuit board 2, and for connecting the conductor paths 6 and 6′ with terminal pins 8, 9 of the electronic component 3.

In the exemplary embodiment illustrated in FIG. 1, the power semiconductor component 3 has two terminal pins 8 and 9. The pins 8 and 9 of the power semiconductor component 3 are soldered in the through holes 7 of the electronic circuit board 2. The solder 10 fixes the pins 8 and 9 in the through holes 7, and consequently, fixes the power semiconductor component 3 on the electronic circuit board 2. In addition, the solder 10 creates a thermal and electrical connection between the terminal pins 8, 9 of the power semiconductor component 3 and the conductor path 6, equally for the terminal pin 9 and the conductor path 6′. Therefore, the heat produced in the power semiconductor component 3 can be transported away via the conductor paths 6 and 6′.

The copper block 4 includes a fixing pin 11 for the connection with the electronic circuit board 2. The copper block 4 is soldered to the conductor path 6 in the same way as the power semiconductor component 3. The copper block 4 is soldered to the conductor path 6 such that the bottom surface 4.1, for example, the entire bottom surface, of the copper block 4 is soldered to the conductor path 6. Therefore, maximum heat flow between the copper block 4 and the conductor path 6 is achieved. A thermal connection is now established between the power semiconductor component 3 and the copper block 4 by the conductor path 6. The copper block 4 is mounted as close as possible to the power semiconductor component 3 without any further electronic components in between for not heating up additional components and for an improved heat flow from the power semiconductor component 3 to the copper block 4. Certainly, the arrangement of the copper block 4 has to respect distances to the power semiconductor component 3 which could disturb the functionality of the power semiconductor component 3 by electromagnetic emissions or by direct current flow over the exterior walls of the power semiconductor component 3 and the copper block 4. If such a direct contact between the power semiconductor component 3 and the copper block 4 does not disturb the functionality of the power semiconductor component 3, the heat flow from the power semiconductor component 3 to the copper block 4 can further be improved by the heat flow over the outer walls of the power semiconductor component 3 and directly to the copper block 4. In contrast thereto, it is even possible to arrange a further component on the conductor path 6 between the copper block 4 and the power semiconductor component 3, such as a further component which is not sensible to heat and does not produce too much heat such that the heat flow from the power semiconductor component 3 to the copper block 4 is not remarkably disturbed.

The heat of the power semiconductor component 3 and/or of the copper block 4 can be removed by natural convection or by the support of a fan, for example.

In the following, the functionality of various features of the present disclosure is described on the basis of the first exemplary embodiment illustrated in FIG. 1. The heat produced in the power semiconductor component 3 flows into the conductor paths 6 and 6′ and is transported away. During normal operating currents, the heat of the power semiconductor component 3 is dissipated efficiently without consideration of the copper block 4, because the heat transport characteristics are designed for heat production during normal operating currents. During transient overloads, an overload current appears for a short time in the power semiconductor component 3 and the temperature therein rises. Therefore, the heat flow out of the power semiconductor component 3 increases. Since the increased heat amount cannot be completely conducted away by the overburdened conductor path 6, the heat flows partly into the copper block 4. The copper block 4 buffers the heat during this heat maximum and releases the heat slowly after such a heat production maximum. Thus, the copper block 4 can buffer a certain amount of heat and can smooth the temperature rise in the power semiconductor component 3 during high currents for a limited time period. This has the advantage that temperatures due to short time overload currents can be overcome by simply buffering the heat energy and not by complex and expansive design changes in the electronic circuit board 2 which are needed only for small time periods. An example of the length of the transient current is up to two seconds for low voltage drives, for example, and soft starters can have startup transients of up to 30 seconds, for example. Therefore, as an example, the required heat capacity of the copper block 4 is calculated based on a transient current period of 30 seconds.

In other words, the copper block 4 significantly reduces the thermal impedance of the system out of the power semiconductor component 3, the copper block 4 and the conductor paths 6, 6′ and increases its thermal capacitance. Consequently, more heat is transported away over the conductor path 6. Certainly, the heat flow from the power semiconductor component 3 can be further improved by an additional copper block 4 on the second terminal side of the power semiconductor component 3, i.e. mounted on the conductor path 6′ (e.g., to the right of the power semiconductor component 3 with reference to the exemplary embodiment illustrated in FIG. 1). This can be generalized to each terminal of an electronic component. FIG. 8 shows a conductor path 27 with a plurality of copper blocks 28.1, 28.2 and 28.3 mounted thereon. This arrangement increases the heat capacitance of the conductor path for buffering the heat produced during transient currents. As shown in FIG. 8, a plurality of small copper blocks 28.1, 28.2 and 28.3 can be provided as a substitute for a big copper block such as copper block 4 illustrated in FIG. 1. This arrangement saves construction space and provides an improved distribution of the heat of the semiconductor component 3 or 14.

The functionality of the copper block 4, i.e. the buffering and transmitting of the heat produced during transients, defines the design of copper block 4, i.e. the heat capacitance of the copper block 4, and the distance from the component, for example the power semiconductor component 3 such as illustrated in FIG. 1. The copper block 4 is designed and arranged in a distance to the electronic component such that the power semiconductor component 3 and the electronic circuit board 2 around the power semiconductor component 3 remain under a thermal threshold during an operating state of the power semiconductor component 3, such as when a transient current is larger than the nominal current of the power semiconductor component 3. The thermal threshold is defined by solder limits, which can be, for example, limits warranted for the power semiconductor component 3 by the manufacturer, limits warranted for neighboring components by the manufacturer, or limits of the electronic circuit board 2. According to an exemplary embodiment, a good condition to fulfill such a thermal threshold is to buffer at least ⅔ of the heat produced by the power semiconductor component 3 and transmitted by the copper block 4.

FIG. 2 and FIG. 3 show a second and a third exemplary embodiment of the present disclosure, respectively. The functionality of the second and third exemplary embodiments corresponds basically to the first exemplary embodiment illustrated in FIG. 1. FIG. 2 shows the second exemplary embodiment of the disclosure 13 where a power semiconductor component 14 and a copper block 15 are soldered by a surface mounted device (SMD) technique to an electronic circuit board 13. Here, the components 14 and 15 are glued to the electronic circuit board 13 and fixed laterally by solder 10. The power semiconductor component 14 and the copper block 15 are thermally and electrically connected by solder 10 to the conductor path 6 of the electronic circuit board 13. The power semiconductor component 14, the copper block 15 and the electronic circuit board 13 have the same design and arrangement as in the first embodiment of the present disclosure except for a different fixing system. Therefore, the electronic circuit board 13 has no through, holes and the power semiconductor component 14 and the copper block 15 have no pins. There are several fixing techniques such as clipping, brazing, press-fitting, sintering, snap-fitting, for example, which can be used as alternatives of the one illustrated in FIG. 2.

FIG. 3 shows a third exemplary embodiment of the present disclosure. The electronic circuit board 16 has the same components, i.e. the power semiconductor component 3, the copper block 4, the insulating substrate 5 and the conductor paths 6 and 6′ as in the first embodiment of the disclosure. Only an alternative arrangement of the copper block 4 is shown. In the electronic circuit board 2 of the first embodiment, the heat flows over the conductor path 6 to the copper block 4 being mounted on the same side of the electronic circuit board 2 as the power semiconductor component 3. For very high currents, the heat of the power semiconductor component 3 may not be conducted rapidly enough to the copper block 4, because the conductor path 6 might constitute a bottleneck in the thermal flow system including the power semiconductor component 3, conductor path 6 and copper block 4. This problem is solved by the arrangement of the copper block 4 on the other side of the electronic circuit board 2, on the same terminal pin 8. Thus, the terminal of the power semiconductor component 3 faces the terminal of the copper block 4 such that a direct thermal connection between the power semiconductor component 3 and the copper block 4 exists without the potential bottleneck of the conductor path 6. If the direct connection has a larger cross-sectional area in the heat flow direction than the conductor path 6, the heat transport capability of the system is improved. In some applications, it is even advantageous to arrange the copper block 4 on the opposite site, because next to the power semiconductor component 3 the space may already be occupied by further electronic components. The copper block 4 can even have its own pin which is fixed in the same through hole as the pin 8 of the power semiconductor component 3 or is fixed in a second neighboring through hole such that both pins are connected by the solder 10. This additionally improves the cross-sectional area in the heat flow direction of the direct connection between the power semiconductor component 3 and the copper block 4, because the cross-sectional area of the connection limited by the cross-sectional of the through hole is doubled.

According to an exemplary embodiment, if the copper block 4 is on the same side as the power semiconductor component 3, it is advantageous to form the copper block 4 such that copper block 4 has the same or a similar height as the power semiconductor component 3 as shown in the drawings. As used herein, the term “height” means the distance in a perpendicular direction from the electronic circuit board 2 between the electronic circuit board 2 and the point of the copper block 4. In addition or alternatively, the depth of the copper block 4 can be chosen to be similar to the depth of the power semiconductor component 3. As used herein, the “depth” is the dimension in direction which is rectangular in the plane of projection, i.e. the direction being rectangular to the direction of the height and rectangular to the direction formed by the line arrangement of the copper block 4 and the power semiconductor component 3. If the copper block 4 has the same height and the same depth as the power semiconductor component 3, the copper block 4 does not project over the power semiconductor component 3 in the two described directions. This saves worthy space for components in the vicinity.

In general, the size of the copper block 4 regulates the amount of heat the copper block 4 can buffer and thus, how much additional heat produced by transient electrical overloads can be buffered therein. In combination with the adaption of the dimensions of the copper block 4, the size can be regulated about the dimension in the third direction pointing from the power semiconductor component 3 to the copper block 4. Alternatively, the dimension of the copper block 4 can be chosen by the free space on the electronic circuit board 2. To further save construction space, the form of the copper block 4 on the side facing the power semiconductor component 3 can be chosen to complimentarily correspond to the side of the power semiconductor component 3 facing the copper block 4, e.g., that a shell surface of the copper block 4 is at least partially complementary to a shell surface of the power semiconductor component 3. For example, if the power semiconductor component 3 is formed like a cylinder and the circular outer wall of the cylinder points versus the copper block 4, one outer wall versus the power semiconductor component 3 can be chosen as the corresponding concave cylinder form. Thus, the copper block 4 can be arranged very close to the power semiconductor component 3. If the copper block 4 is designed such that the copper block 4 surrounds the power semiconductor component 3 laterally and if the copper block 4 including an opening near the surface of the electronic circuit board 2, a chimney effect can be created. The chimney effect additionally supports the cooling effect of the power semiconductor component 3 and of the copper block 4, while the construction space around the power semiconductor module 3 is effectively used.

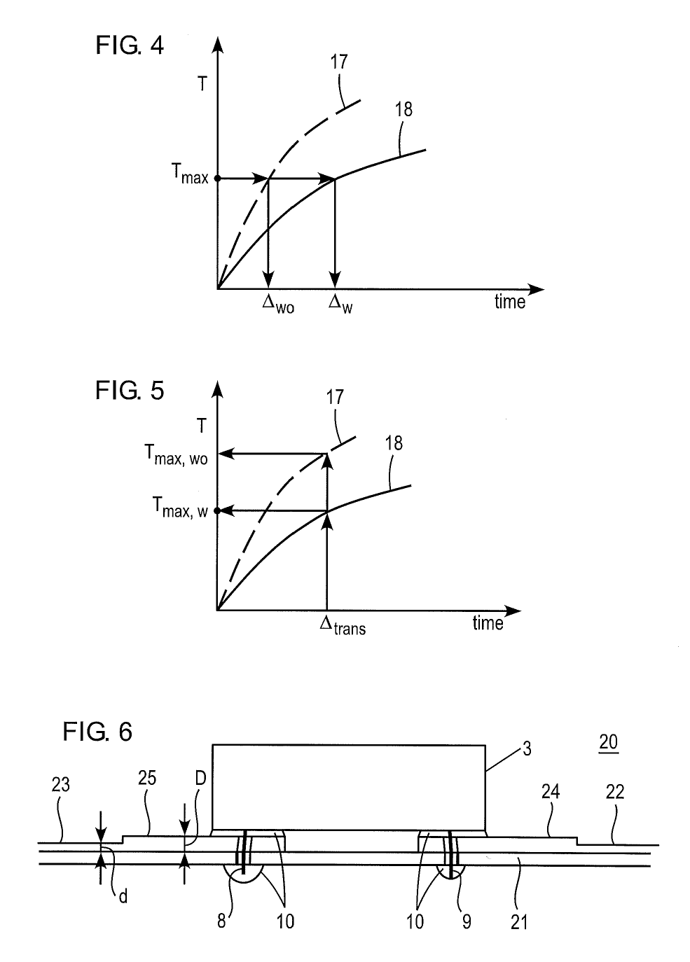

FIGS. 4 and 5 show the temperature (T) of the power semiconductor component 3 over time (t) during a transient overload current in the power semiconductor component 3. Line 17 shows the temperature-rise of a power semiconductor component 3 or 14 without a neighboring copper block 4, and line 18 the temperature-rise of the power semiconductor component 3 or 14 with the neighboring copper block 4 or 15. The temperature line 17 increases much faster than the temperature line 18 of the exemplary electronic circuit 1, 12 or 16. Without a copper block, the maximal temperature Tₘₐₓ of the power semiconductor component is reached rapidly after the time period tΔ_{wo}. In the exemplary embodiments of the electronic circuit according to the present disclosure, a maximal allowed temperature Tₘₐₓ is reached later after the time period tΔ_{w}. In the exemplary embodiments of the electronic circuit according to the present disclosure, the transient overload current can be applied longer than in electronic circuits without a copper block 4 or 13 as a thermal capacitor, for example. FIG. 5 shows that a power semiconductor component 3 after the transient overload current applied for the time period tΔₜᵣₐₙₛ to the power semiconductor component 3 without a neighboring copper block 4 shows higher temperature T_{max, wo} than the temperature T_{max, w} of the power semiconductor component 3 or 14 with a neighboring copper block 4. Thus, for a given transient time period tΔₜᵣₐₙₛ, the temperature T at the end of the transient current overload is reduced with the copper block 4 in vicinity of the power semiconductor component 3 or 14.

The thermal capacitor is not restricted to copper. Any material having good heat transportation properties for rapidly absorbing heat energy into the thermal capacitor 3 or 14 and a relatively large heat capacitance are possible, such as aluminium, any alloys of aluminium, copper and/or copper alloys, for example. Metals in general are advantageous, because they have high heat flow properties and are well connectable by soldering to the conductor path 6. However, the thermal capacitor can even be made of a composite material such as a metal matrix component, nano carbons, nanotubes and the like, as long as the thermal capacitor has a good thermal conductivity.

FIG. 6 shows an electronic circuit board 20 according to a fourth exemplary embodiment of the present disclosure. The electronic circuit board 20 has an insulating layer 21 and two conductor paths 22 and 23. The conductor paths 22 and 23 have through holes as the electronic circuit board 2. The power semiconductor component 3 is the same as in any of the first and third exemplary embodiment of the present disclosure, and is soldered to the conductor paths 22 and 23 through pins 8 and 9 in the through holes. The conductor paths 22 and 23 each show a region 24 and 25, respectively, in closer vicinity to the electronic component 3 with an increased thickness D as thermal capacitor region, compared to the regions of the conductor path being further away having a thickness d. The distance is measured by following the conductive connection. Here, the thickness is the dimension in the direction perpendicular to the plane of the electronic circuit board 20. In this exemplary embodiment, the conductor paths 22 and 23 show a step in the thickness of the conductor paths 22 and 23, when the regions 24 and 25 are entered. Instead of a step, even a continuous increase in thickness is realizable. In the illustrated exemplary embodiment, the semiconductor component is mounted directly on the regions 24, 25 with the increased thickness.

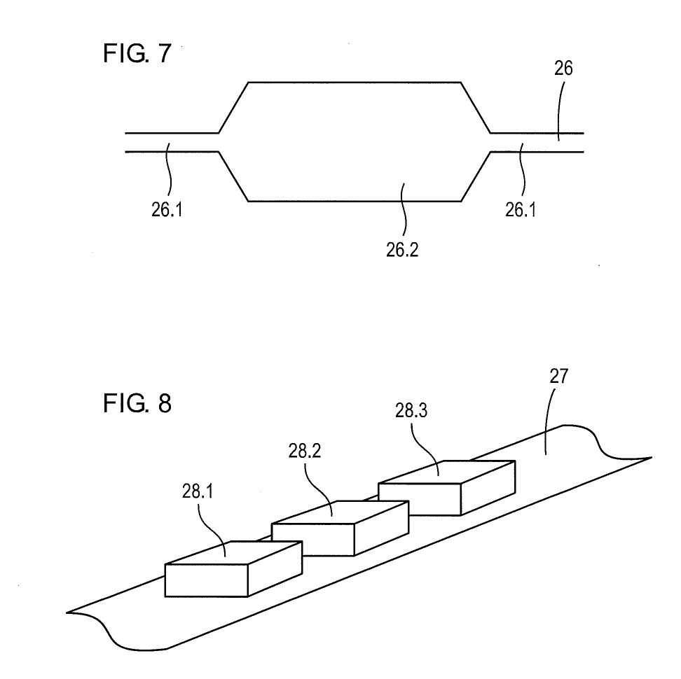

The thickness d of the conductor paths 22 and 23 can be increased to thickness D only by a small amount with minor elevation of the position of the power semiconductor component 3 (not shown). In another exemplary embodiment, the thickness of the conductor paths 22, 23 in a region directly between the power semiconductor component 3 and the substrate 21 is not increased such that the power semiconductor component 3 is not elevated. The region directly neighboring the power semiconductor component 3 and the region under the power semiconductor component 3 is increased in thickness for enlarging the thermal capacitance of the conductor paths 22, 23. In accordance with another exemplary embodiment, instead of the thickness or in addition to the thickness increase, the width of the conductor path can be enlarged in vicinity of the power semiconductor component 3 as shown in FIG. 7. FIG. 7 shows the conductor path 26 according to a fifth exemplary embodiment of the disclosure. The conductor path 26 increases from a region 26.1 of normal width of the conductor path 26 to a region 26.2 of increased width of the conductor path 26 for further increasing the thermal capacitance of the conductor path 26 in the region 26.2. It may prove to be advantageous if the power semiconductor component 3 is mounted in the region 26.2. Here, the width is the dimension in the direction which is parallel to the plane of the electronic circuit board and rectangular to the thermal and electrical conducting direction. The fourth and fifth exemplary embodiments of the disclosure are advantageous for applications with increased space on the electronic circuit board 20.

The first, second, third, fourth, fifth and/or sixth exemplary embodiment of the disclosure and their variations can be advantageously combined to further increase the thermal capacitance of the conductor path in vicinity of a power semiconductor component 3 or 14. Such a circuit board with a conductor path 22, 23 increased in thickness in vicinity of the power semiconductor component 3 and with a thermal capacitor 4 mounted in vicinity to the power semiconductor component 3 can be a solution for extreme high maximum currents or for overload currents which are applied a longer, but still limited period of time.

The present disclosure is not limited to power semiconductor components, but applicable for all kinds of electronic components and heat emitting components on electronic circuit boards. The present disclosure is especially advantageous for power semiconductor components such as 3 and 14, because very high currents are applied to power semiconductor components 3 and 14 and they are quite sensible to high temperatures.

According to an exemplary embodiment, the thermal capacitor can be mounted or the thermal capacitor region can be designed on the electronic circuit board 2 at every electronic component which shows for short times high currents or at every electronic component which is shortly heated up over a heat amount which can be transported away by the electronic circuit board. For very high maximal currents, large thermal capacitors or very thick and large thermal capacitor regions can be applied. In addition, a thermal capacitor or a thermal capacitor region can be mounted or designed on more conductor paths around the electronic component, such as at all conductor paths being connected with the electronic component, for example.

The present disclosure is not limited to printed circuit boards, and it can be applied to any kind of circuit boards. The circuit board shown in the illustrated exemplary embodiments has two conductors, but any number of conductors is possible.

The present disclosure is not limited to the described embodiments. All embodiments described are combinable with each other. An exemplary embodiment does not restrict the disclosure to the exemplary embodiment, alternatives or combinations with other embodiments are included in the scope of protection.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. An electronic circuit board comprising:
at least one conductor path;
at least one component being one of an electronic component, an electric component and a heat emitting component, the component being connected to the at least one conductor path;
at least one thermal capacitor configured to buffer thermal energy in an operating state of the electronic circuit board, the at least one thermal capacitor being thermally connected to at least one of the conductor path in vicinity to the at least one component, and the at least one conductor path,
wherein the at least one thermal capacitor comprises at least one material having heat transportation properties for rapidly absorbing thermal energy discharged by the component during overload of the component over the conductor path in an operating state of the electronic circuit board.

2. The electronic circuit board according to claim 1, wherein the at least one thermal capacitor is configured to temporally buffer the energy and slowly release heat of the thermal energy to the conductor path and to an ambient environment of the electronic circuit board when a transient overload of the component is finished.

3. The electronic circuit board according to claim 1, wherein the at least one thermal capacitor of the circuit board is thermally connected to the conductor path neighboring the at least one component and on a same side of the electronic circuit board as the at least one component.

4. The electronic circuit board according to claim 1, wherein the at least one thermal capacitor is connected to the conductor path on an averted side of the at least one component of the electronic circuit board.

5. The electronic circuit board according to claim 1, wherein the at least one thermal capacitor comprises at least one material having a heat conductance value of at least a heat conductance value of the conductor path.

6. The electronic circuit board according to claim 5, wherein the at least one thermal capacitor comprises at least one of copper and aluminium.

7. The electronic circuit board according to claim 1, wherein the at least one thermal capacitor is east one of soldered, brazed, clipped, press-fitted, sintered and snap-fitted to the at least one conductor path.

8. The electronic circuit board according claim 1, wherein the at least one thermal capacitor comprises a first shell surface, and the at least one component comprises a second shell surface partially complementary to the first shell surface of the at least one thermal capacitor.

9. The electronic circuit board according to claim 1, wherein the at least one thermal capacitor is located at a distance from the at least one component such that a thermal load being fed in the conductor path by the at least one component in an operating state of the electronic circuit remains below a preselected thermal threshold.

10. The electronic circuit board according to claim 9, wherein at least two-thirds of the thermal load emitted from the at least one component is received by the at least one thermal capacitor appointed to the at least one component.

11. The electronic circuit board claim 1, comprising a plurality of thermal capacitors connected to the conductor path.

12. The electronic circuit board according to claim 1, comprising an additional component electrically connected to the at least one conductor path connecting the at least one component and the at least one thermal capacitor.

13. The electronic circuit board according to claim 1, wherein the at least one thermal capacitor is configured to buffer therein additional heat of transient currents being higher than a nominal current of at least one of the at least one component and the conductor path for a predetermined period of time.

14. The electronic circuit board according to claim 1, wherein the at least one thermal capacitor and the at least one component are each thermally connected by means of the same connection to the conductor path.

15. The electronic circuit board according to claim 14, wherein the connection has a larger cross-sectional area in the direction of the heat flow than the conductor path.

16. The electronic circuit board according to claim 1, wherein the at least one conductor path has a thickness of a first dimension and a width of a second dimension, and
wherein the at least one conductor path has at least one thermal capacitor region having at least one of (i) a thickness greater than the first dimension, (ii) a width greater than the first dimension, and (iii) a width greater than the second dimension in vicinity to at least one of the at least one component configured to transmit or buffer thermal energy and the at least one conductor path.

17. The electronic circuit board according to claim 2, wherein the at least one thermal capacitor of the circuit board is thermally connected to the conductor path neighboring the at least one component and on a same side of the electronic circuit board as the at least one component.

18. The electronic circuit board according to claim 2, wherein the at least one thermal capacitor comprises at least one material having a heat conductance value of at least a heat conductance value of the conductor path.

19. The electronic circuit board according to claim 3, wherein the at least one thermal capacitor comprises at least one material having a heat conductance value of at least a heat conductance value of the conductor path.

20. The electronic circuit board according to claim 2, wherein the at least one thermal capacitor is located at a distance from the at least one component such that a thermal load being fed in the conductor path by the at least one component in an operating state of the electronic circuit remains below a preselected thermal threshold.

21. The electronic circuit board according to claim 1, wherein the at least one thermal capacitor is configured to temporally buffer the energy and release heat of the thermal energy to the conductor path and to an ambient environment of the electronic circuit board during a transient overload of the component.

22. The electronic circuit board according to claim 12, wherein the additional component is a heat insensible component.

23. The electronic circuit board according to claim 13, wherein the predetermined period of time includes at least 100 seconds.

24. The electronic circuit board according to claim 13, wherein the predetermined period of time includes at least 30 seconds.

25. The electronic circuit board according to claim 3, wherein the at least one thermal capacitor and the at least one component are each thermally connected by means of the same connection to the conductor path.

26. The electronic circuit board according to claim 25, wherein the connection has a larger cross-sectional area in the direction of the heat flow than the conductor path.
